(19) United States
(12) Patent Application Publication
(10) Pub. No.: US 2026/0138313 A1
(43) Pub. Date: May 21, 2026

(54) MOLDING APPARATUS, INFORMATION PROCESSING APPARATUS, MOLDING METHOD, NON-TRANSITORY COMPUTER-READABLE STORAGE MEDIUM, AND ARTICLE MANUFACTURING METHOD

(71) Applicant: CANON KABUSHIKI KAISHA, Tokyo (JP)

(72) Inventor: HIROMU KIJIMA, Tochigi (JP)

(21) Appl. No.: 19/376,043

(22) Filed: Oct. 31, 2025

(30) Foreign Application Priority Data
Nov. 19, 2024 (JP) 2024-201655

(51) Int. Cl. B29C 43/58; B29C 43/18; B29L 31/34; G03F 7/00; H01L 21/027; H01L 21/311

(52) U.S. Cl. CPC B29C 43/58; B29C 43/18; G03F 7/0002; H10P 76/00; B29L 2031/3406; H10P 50/73

(57) ABSTRACT

A molding apparatus for forming a liquid film comprising a curable composition in a space between a substrate and a mold by bringing the mold into contact with a plurality of droplets of the curable composition disposed on the substrate, including, a control unit configured to determine an adjustment method of an arrangement of the plurality of droplets based on a spread region which is acquired based on the arrangement of the plurality of droplets on the substrate and is a region where the plurality of droplets spread due to the contact with the mold, and an outer peripheral boundary determined based on a shape of an outer peripheral portion of the substrate.

### BACKGROUND

### Field of the Technology

The disclosure relates to a molding apparatus, an information processing apparatus, a molding method, a non-transitory computer-readable storage medium, and a method of manufacturing an article.

### Description of the Related Art

There is an imprint technique of forming a fine pattern by bringing a mold having a fine pattern (concave-convex pattern) formed thereon into contact with an imprint material (for example, a photocurable resin) supplied onto a substrate. This imprinting technique is attracting attention as one of nanolithography techniques for mass production of semiconductor devices and magnetic storage media. Imprint technology is also used in flattering technology for manufacturing semiconductor devices.

In imprint processing or flattering processing, there is a technique of forming an array of droplets of an imprint material on a substrate using an inkjet method. The mold is brought into contact with the droplets of the imprint material arranged on the substrate to fill concave portions of a pattern of the mold with the imprint material, and the imprint material is cured to form the pattern. In order to form a defect-free pattern or a uniform flat surface on a substrate, it is necessary to adjust a drop recipe which is application information indicating a supply position of droplets (drops) of the imprint material on the substrate.

Japanese Patent Laid-Open No. 2012-506600 discloses a method of generating a drop recipe using a Voronoi diagram. Japanese Patent Laid-Open No. 2022-124336 discloses a method of simulating the spread shape of a drop using fluid calculation.

In order to correct a defect including an un-filling and/or extrusion by adjusting the droplets, it is necessary to correctly predict the spread of the droplets in the outer peripheral portion of the substrate.

The method using the Voronoi diagram disclosed in Japanese Patent Laid-Open No. 2012-506600 is effective mainly for predicting the spread shape of a droplet inside a shot region, however the spread shape of a droplet may be incorrectly predicted in the outer peripheral portion of a substrate. In addition, in Japanese Patent Laid-Open No. 2022-124336, the spread shape of the liquid droplets can be predicted even in the outer peripheral portion of the substrate by performing a simulation involving fluid calculation, however a large amount of calculation resources is required.

### SUMMARY

The present disclosure provides a molding apparatus capable of predicting the spread of a plurality of droplets of a curable composition on the outer peripheral portion of a substrate and determining a method of adjusting the arrangement of the droplets from the prediction result.

According to one aspect of the present disclosure, a molding apparatus for forming a liquid film comprising a curable composition in a space between a substrate and a mold by bringing the mold into contact with a plurality of droplets of the curable composition disposed on the substrate, includes a control unit configured to determine an adjustment method of an arrangement of the plurality of droplets based on a spread region which is acquired based on the arrangement of the plurality of droplets on the substrate and is a region where the plurality of droplets spread due to the contact with the mold, and an outer peripheral boundary determined based on a shape of an outer peripheral portion of the substrate.

According to the present disclosure, it is possible to provide a molding apparatus capable of predicting the spread of a plurality of droplets of a curable composition on the outer peripheral portion of a substrate and determining a method of adjusting the arrangement of the droplets from the prediction result.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic view showing a configuration of a molding apparatus of the

present disclosure.

FIG. 2 is a diagram illustrating a configuration example of an information processing apparatus according to an embodiment of the present disclosure.

FIG. 3 is a diagram illustrating a configuration example of hardware in which the information processing apparatus according to the embodiment of the present disclosure is implemented.

FIG. 4 is a diagram illustrating an example of application information of an imprint material.

FIG. 5 is a diagram for explaining the supply of an imprint material onto a substrate.

FIG. 6 is a diagram showing an example of an operation screen of an editor functioning as a user interface.

FIG. 7 is a diagram showing an example in which a part of the application information of the imprint material is deleted in accordance with the shape of the outer periphery of the substrate.

FIG. 8 is a diagram illustrating a feature of a shape of a substrate edge.

FIG. 9 is a view showing a flow of the imprint material adjustment of the outer peripheral portion of the substrate.

FIG. 10 is a diagram showing a flow of predicting the spread shape of the imprint material in the outer peripheral portion of the substrate.

FIG. 11 is a diagram illustrating an example in which a Voronoi diagram is calculated based on the arrangement of the imprint material.

FIG. 12A and FIG. 12B are diagrams illustrating the spread of the vertex of the spread region with respect to the Voronoi region.

FIG. 13 is a diagram illustrating an example of a spread shape of a spread region.

FIG. 14 is a diagram illustrating an example of calculating an adjustment vector of an arrangement of the imprint material based on the spread shape and the outer peripheral boundary.

FIG. 15 is a diagram illustrating an example of calculating an adjustment vector of the arrangement of the imprint material based on the spread shape and the outer peripheral boundary.

FIG. 16 is a diagram illustrating an example of calculating an adjustment vector of the arrangement of the imprint material based on the spread shape and the outer peripheral boundary.

FIG. 17 is a diagram illustrating an example in which the volume of the imprint material is adjusted based on the spread shape and the outer peripheral boundary.

FIG. 18 is a diagram illustrating an example in which the arrangement of a droplet of the imprint material is deleted.

FIG. 19 is a diagram illustrating an example in which the position of the imprint material is adjusted.

FIG. 20 is a diagram illustrating an example of calculation of a spread shape of a closed Voronoi region.

FIG. 21 is a diagram illustrating a method of calculating a spread shape of a closed Voronoi region.

FIG. 22 is a diagram illustrating an example of adding droplets of an imprint material.

FIG. 23A is a schematic diagram illustrating a method of manufacturing an article.

FIG. 23B is a schematic diagram illustrating the method of manufacturing an article.

FIG. 23C is a schematic diagram illustrating the method of manufacturing an article.

FIG. 23D is a schematic diagram illustrating the method of manufacturing an article.

FIG. 23E is a schematic diagram illustrating the method of manufacturing an article.

FIG. 23F is a schematic diagram illustrating the method of manufacturing an article.

### DESCRIPTION OF THE EMBODIMENTS

There is an imprint technique of forming (transferring) a fine pattern by bringing a mold M having a fine pattern (concave-convex pattern) formed thereon into contact with an imprint material R supplied onto a substrate S.

This imprinting technique is attracting attention as one of nanolithography techniques for mass production of semiconductor devices and magnetic storage media. One of the imprint techniques is a photo-curing method using a photo-curing resin as the imprint material R. In the imprint apparatus employing the photocuring method, first, the imprint material R is supplied (applied) onto the substrate S. Next, the mold (mold) M on which the pattern is formed is irradiated with light such as ultraviolet rays in a state of being in contact with the imprint material R to cure the imprint material, and then the pattern is formed on the substrate S by releasing the mold.

Imprint technology is also used in flattening processing when manufacturing semiconductor devices. For example, the manufacturing process of the semiconductor device includes repeating the addition and removal of a material to the substrate S. This process produces a layered substrate with irregular height variation (i.e., topography), and as more layers are added, the height variation of the substrate S increases. The height variation affects the ability to add additional layers to the layered substrate.

Alternatively, a semiconductor substrate (e.g., silicon wafer) itself is not necessarily completely flat, but includes an initial surface height variation (i.e., topography). To address this problem, a process may be included to planarize the substrate surface during the lamination process. Various lithographic patterning methods benefit from patterning a plane. In ArF laser based lithography, the flattening improves depth of focus (DOF), critical dimension (CD), and critical dimension uniformity.

In the imprint process or the flattening process, when the resin, that is, the imprint material R is supplied onto the substrate S, droplets of the imprint material R are arranged on the substrate S using, for example, an inkjet method. Then, by bringing the droplets of the imprint material R on the substrate and the mold M into contact with each other, the imprint material R is filled (permeated) into concave portions of the pattern of the mold M.

However, in the imprint apparatus, a defect may occur in the pattern formed on the substrate S due to a difference in the pattern of the mold M, manufacturing variation, or the like, and it is difficult to always form a good-quality pattern or a uniform flat surface. In order to avoid this problem, it is necessary to adjust a drop recipe (imprint recipe) which is application information (application pattern) indicating a supply position of droplets of the imprint material R on the substrate S.

After the imprint process, the application pattern is corrected until there is no defect. Examples of the defect include “un-filling” in which the imprint material R is not filled between the mold M and the substrate S, and “extrusion” in which the imprint material R protrudes from the imprint region.

The shape of the outer peripheral portion of the substrate S is generally a curved surface (curved shape, arc shape). The coordinate information of the droplets of the imprint material R of the application pattern is compared with the cutting range including the curved surface shape portion, and coordinates of the droplets of the imprint material R outside the range are deleted to generate the adjusted drop recipe. In many cases, the coordinate information of the droplets of the imprint material R of the application pattern is generated in a range including a desired dropping range and larger than a range including the curved surface portion. However, in the method of generating the drop recipe, unevenness occurs in the density of the droplets and a distance from the outer peripheral portion of the substrate S to the droplet due to the influence of the coordinate information of the droplets before cutting, and the above-described un-filling or extrusion occurs.

When the un-filling occurs in the outer peripheral portion of the substrate, there is a possibility that an overlapping accuracy is deteriorated due to a contact between the substrate S and the mold M or the mold M is damaged. The extrusion at the outer peripheral portion of the substrate may cause an influence that the imprint material R flows out of the imprint range or the imprint material R remains adhered to a part of the mold M, thereby causing a defect in the next shot. That is, the defect is taken over to the next shot region. In an actual operation, it is necessary to repeat the imprint process and the correction of the drop recipe, and it takes a long time to correct the drop recipe.

In order to address this problem, when the arrangement of the droplets of the imprint material R on the outer peripheral portion of the substrate is adjusted, it is necessary to finely designate the cutting or to adjust the droplets likely to cause defects (change the positions of the droplets or change the amounts of the droplets). Not only in the case of cutting by simple droplet coordinates, but also in the case of suppressing the extrusion and the un-filling at the outer peripheral portion of the substrate, it is necessary to identify the droplets causing these defects and adjust the arrangement of the droplets. It is possible to associate the defect with the droplet by predicting how the droplet spreads due to the contact between the imprint material R on the substrate S and the mold M.

In order to correct the defect including the extrusion and/or the un-filling of the droplets of the imprint material R in the outer peripheral portion of the substrate by adjusting the droplets, it is necessary to correctly predict the spread of the droplets in the outer peripheral portion of the substrate.

There is a method of predicting the spread of droplets using a Voronoi diagram of a geometric shape. The Voronoi diagram is a diagram in which a certain distance space are divided into regions depending on which site among a plurality of sites arranged at arbitrary positions in the distance space a point other than any of sites in the same distance space are close to. This is a method of predicting the spread of droplets by creating a Voronoi diagram using each droplet as a site.

However, although the Voronoi diagram is mainly effective in predicting the spread shape of a droplet inside a shot, the spread shape of a droplet may be incorrectly predicted because the Voronoi region is calculated to be very large in the outer peripheral portion of the substrate. In addition, although the spread shape can be predicted even in the outer peripheral portion of the substrate by performing the simulation accompanying the fluid calculation, a large amount of calculation resources is required.

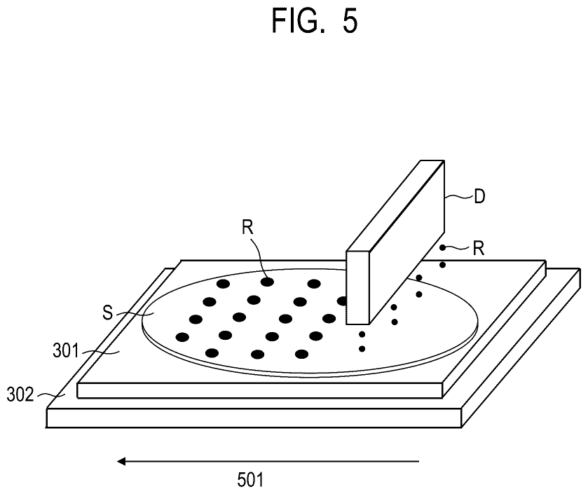

In addition, in order to effectively utilize the substrate S, it is necessary to uniformly dispose the droplets of the imprint material R in a region as wide as possible on the surface of the substrate S. However, since the outer shape of the substrate S is circular (the outer peripheral portion is a curved shape), it is not possible to make the relationship between the droplet disposed at the outermost peripheral portion of the substrate S and the outer peripheral portion of the substrate S uniform among the droplets of the imprint material R disposed in a lattice manner by a method described later with reference to FIG. 5. Therefore, it is necessary to correctly predict the spread of the droplets on the outer peripheral portion of the substrate in order to correct the defect including the extrusion and/or the un-filling of the droplets of the imprint material R on the outer peripheral portion of the substrate by adjusting the position, amount, and presence of the droplets.

The present disclosure shows a method of predicting spread of a droplet of an imprint material in an outer peripheral portion of a substrate and adjusting the droplet based on a result of the prediction. Hereinafter, preferred embodiments of the present disclosure will be described in detail with reference to the accompanying drawings.

### Embodiment

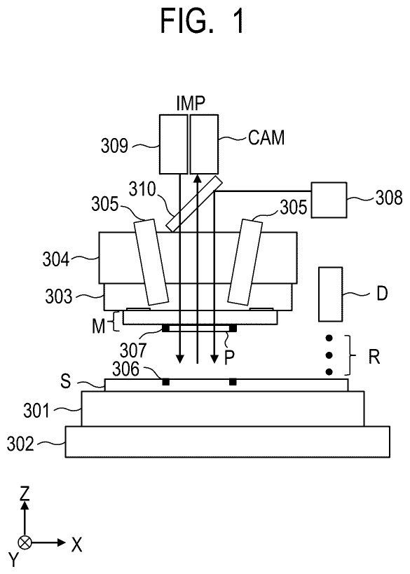

FIG. 1 is a schematic diagram illustrating a configuration of a molding apparatus IMP (film forming apparatus) according to the present embodiment. The molding apparatus IMP is an apparatus that forms a film on the substrate S using a mold (mask) M. The molding apparatus IMP forms a pattern film or a flat film in a plurality of shot regions of the substrate S by repeating the imprint process.

Here, the film forming process refers to a series of cycles including supplying of the imprint material R to the substrate S, bringing the mold M and the imprint material R in contact with each other, filling a pattern P of the mold M with the imprint material R, aligning, curing (exposure), and releasing the mold M. In the present embodiment, the shot region means a region having a size corresponding to one pattern P of the mold M, that is, a region (molding region) in which a pattern of the imprint material R corresponding to the pattern P of the mold M is formed in one imprint process.

The curable composition (resin in an uncured state) that is cured by application of energy for curing is used as the imprint material R. Electromagnetic waves, heat, or the like is used ss the curing energy. For example, light such as infrared light, visible light, or ultraviolet light having a wavelength selected from a range of 10 nm or more and 1 mm or less is used as the electromagnetic wave. That is, as the imprint material R, an ultraviolet curable resin which is cured by irradiation with ultraviolet rays may be used, or a thermoplastic or thermosetting resin may be used.

The curable composition is a composition that is cured by irradiation with light or by heating. The photocurable composition which is cured by irradiation with light contains at least a polymerizable compound and a photopolymerization initiator, and may contain a non-polymerizable compound or a solvent, as necessary. The non-polymerizable compound is at least one selected from the group consisting of a sensitizer, a hydrogen donor, an internally added mold release agent, a surfactant, an antioxidant, and a polymer component.

Glass, ceramics, metal, semiconductor, resin, or the like is used for the substrate S, and a member made of a material different from that of the substrate S may be formed on the surface thereof as necessary. Specifically, the substrate includes a silicon wafer, a compound semiconductor wafer, quartz glass, and the like.

The molding apparatus IMP of the present embodiment includes a substrate chuck 301 (substrate holding unit) that holds the substrate S, a substrate stage 302, a mold chuck 303 (mold holding unit), and a mold stage 304 (mold driving unit). It may also include a dispenser (supplying unit) D, an alignment scope 305, a light source 308, a detection light source 309, and a mirror 310.

The substrate chuck 301 holds the substrate S. The substrate chuck 301 holds the substrate S by, for example, a vacuum suction pad or the like. The substrate stage 302 holds the substrate chuck 301 and is driven by a driving mechanism (not shown) to move the substrate S in six axes, thereby aligning the substrate S and the mold M. The drive mechanism may include a plurality of drive mechanisms such as a coarse drive mechanism and a fine drive mechanism. The substrate S is a substrate to which a concave-convex pattern is transferred, and includes, for example, a single crystal silicon substrate or an SOI (Silicon on Insulator) substrate.

The mold chuck 303 holds the mold M on which a pattern (pattern portion) P for transfer is formed or the mold M for flattening. The mold M is held by the mold chuck 303 by, for example, a vacuum suction force, an electrostatic force, or the like. The mold stage 304 holds the mold chuck 303 and drives the mold chuck 303 by a driving mechanism (not shown). The mold M has, for example, a rectangular outer peripheral portion, has a predetermined concave-convex pattern formed in a three-dimensional shape on a surface facing the substrate S, and is made of a material (such as quartz) that transmits ultraviolet light.

The dispenser D can include, for example, a tank that stores the imprint material R, a nozzle (not illustrated) that discharges the imprint material R supplied from the tank through a supply path to the substrate S, a valve provided in the supply path, and a supply amount control unit. For example, the supply amount control unit controls the supply amount of the imprint material R to the substrate S by controlling the valve so that the imprint material R is applied to one shot region in one discharging operation of the imprint material R.

The alignment scope 305 is fixed to the mold stage 304, and detects an alignment mark (substrate-side mark 306) formed on the substrate S and an alignment mark (mold-side mark 307) formed on the mold M. The substrate-side mark 306 is formed in a shot region on the substrate S, and the mold-side mark 307 is formed in the pattern P of the mold M.

A calculation unit 230 in a control unit (controller) 220 described later obtains a relative positional deviation between the mold M and the substrate S from the detection results of the substrate-side mark 306 and the mold-side mark 307 detected by the alignment scope 305. The control unit 220 drives the substrate stage 302 and the mold stage 304 based on the obtained relative positional deviation result to correct the relative positional deviation between the mold M and the substrate S. The relative positional deviation is not limited to the shift component, and includes errors of the magnification and the rotation component. The shape of the pattern P of the mold M can be corrected in accordance with the shot region formed on the substrate S.

As a method of detecting the substrate-side mark 306 and the mold-side mark 307, an interference signal such as a moire signal reflecting the relative positions of the two marks can be used. Alternatively, the relative positions of the two marks may be obtained by detecting the images of the respective marks.

The light source 308 is a light source that emits (irradiates or illuminates) exposure light (ultraviolet rays), and the detection light source 309 is a light source for detection that emits detection light. The mirror 310 is a dichroic mirror and has a characteristic of reflecting the exposure light and transmitting the detection light. The exposure light from the light source 308 is reflected by the mirror 310 and irradiated onto the imprint material R to cure the imprint material R. As a result, a film with the pattern P of the mold M is formed (transferred) or a flattening film is formed on the substrate S.

The detection light from the detection light source 309 passes through the mirror 310, the mold stage 304, and the mold chuck 303, and illuminates a shot region on the substrate S. The detection light illuminating the shot region is reflected by the surface of the substrate S and the pattern surface of the mold M, and the reflected light from the substrate S and the reflected light from the mold M are detected by the image pickup unit CAM as the detection light. By displaying the detection light detected by the image pickup unit CAM on the monitor 201, an operator can observe the state of the imprint process. That is, the image pickup unit CAM can acquire the spread image of the imprint material R when the mold M is brought into contact with the imprint material R, and the image pickup unit CAM has a function as an image acquisition unit. An image obtained by the image pickup unit CAM can be treated as inspection information.

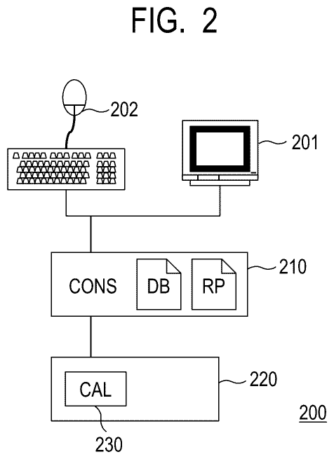

FIG. 2 is a diagram illustrating a configuration example of the information processing apparatus 200 according to the present embodiment. The information processing apparatus 200 can include a console unit 210, a control unit 220, a monitor 201, and an input device 202.

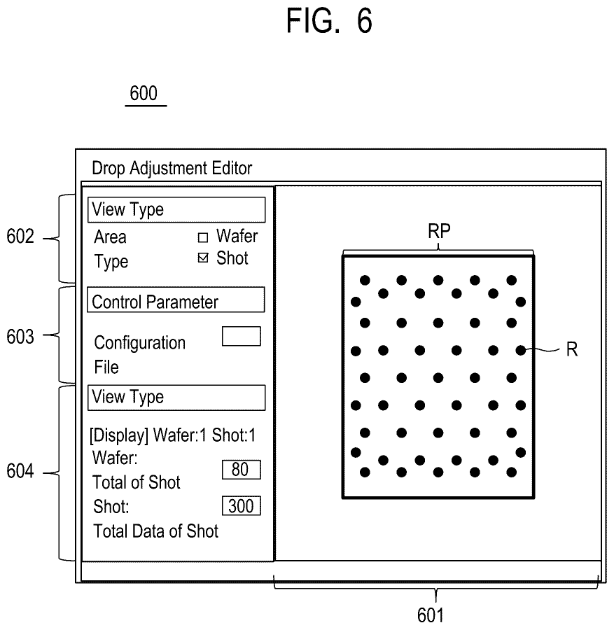

The console unit 210 functions as a user interface, and generates and manages an operation screen (edit screen) such as an editor (Drop Adjustment Editor) 600 described later with reference to FIG. 6, for example. Further, the console unit 210 manages, for example, a database DB and the drop recipe which is the application information RP of the imprint material R, and displays the drop recipe on the monitor 201. That is, the console unit 210 functions as a display control unit. The monitor 201 is a display device that displays an operation screen, and also functions as a display unit. The input device 202 is, for example, a keyboard or a mouse.

The control unit 220 controls each constituent element of the molding apparatus IMP in FIG. 1, for example, the operations of the substrate stage 302, the mold stage 304, and the dispenser D. The control unit 220 can be connected to each constituent element of the molding apparatus IMP by a line (wired or wireless). The method according to the present embodiment is executed by a computer as a program. The control unit 220 includes a computing unit 230.

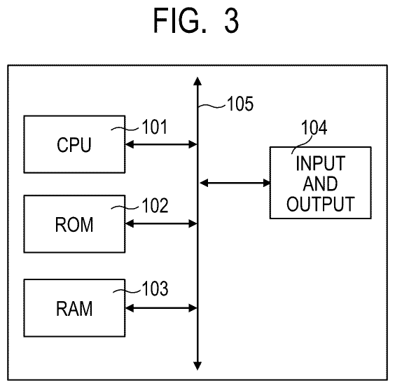

FIG. 3 is a diagram illustrating a configuration example of hardware in which the information processing apparatus 200 according to the present embodiment is implemented. For example, in the film forming process, the information processing apparatus 200 edits a drop pattern so as to correct defects, and displays the result. The information processing apparatus 200 includes a CPU 101, a ROM 102, a RAM 103, and an input/output portion 104 to an external storage device or the like, which are interconnected by a bus 105.

The CPU 101 operates based on a program stored in the ROM 102 or the like, and controls each unit of the information processing apparatus 200. The ROM 102 stores a boot program executed by the CPU 101 when the information processing apparatus 200 is activated, a program dependent on hardware of the information processing apparatus 200, and the like. The CPU 101 implements a flow to be described later by executing a program loaded on the RAM 103, for example. Note that the CPU 101 may acquire these programs from another apparatus via, for example, a network and execute the programs.

The input/output portion 104 inputs an input signal from an external device (an imaging device, an operation device, or the like) in a format processable by the information processing apparatus 200, and outputs the input signal as an output signal in a format processable to an external device (a display device, or the like).

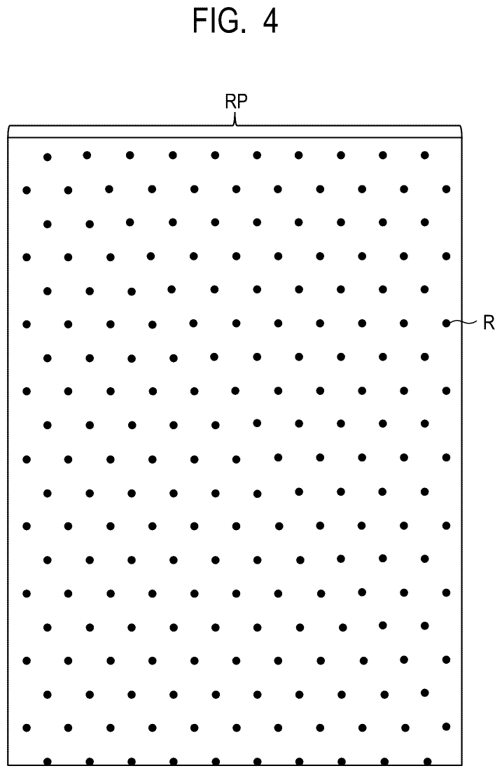

FIG. 4 is a diagram illustrating an example of the arrangement of droplets on the substrate S based on the application information RP of the imprint material R. The application information RP is managed by the console unit 210, and coordinates indicating a position at which the imprint material R is supplied to the substrate S and an amount are set (recorded) as a drop recipe. The control unit 220 controls the substrate stage 302 and the dispenser D so that the imprint material R is supplied to the position on the substrate S set in the application information RP.

FIG. 5 is a diagram for explaining the supply of the imprint material R onto the substrate S. Specifically, FIG. 5 is a diagram illustrating a state in which the imprint material R is supplied (applied) onto the substrate S based on the coordinate information of the application information RP illustrated in FIG. 4. The control unit 220 controls the substrate stage 302 to move the substrate stage 302, for example, in the direction of the arrow 501. Then, droplets of the imprint material R are supplied onto the substrate S by discharging the imprint material R from the plurality of nozzles N arranged in the dispenser D based on the coordinate information of the application information RP. As a result, droplets of the imprint material R are supplied onto the substrate S in an arrangement based on the application information RP.

As a method of supplying the imprint material R onto the substrate S, the imprint material R may be discharged while moving the dispenser D instead of moving the substrate stage 302, or the substrate stage 302 and the dispenser D may be moved relative to each other.

After the imprint material R is applied onto the substrate S based on the application information RP, the mold M is brought into contact with the imprint material R supplied onto the substrate S (stamping, pattern formation), so that the imprint material R fills the concave portion in the pattern P of the mold M.

The surface of the center of the mold chuck 303 on the opposite side to the surface of the pattern P has a recessed portion larger than the region of the pattern P, and is sealed by the mold and a seal glass (not shown). A pressure control unit (not shown) is connected to the sealed space (cavity), and the pressure in the sealed space can be controlled. At the time of stamping, the pressure of the cavity portion is increased to deform the mold M into a convex shape, thereby suppressing air bubbles from being caught between the substrate S and the mold M at the time of stamping.

When the imprint material R on the substrate S and the mold M are brought into contact with each other, the pressure in the cavity portion is restored so that the imprint material R on the substrate S and the mold M are completely brought into contact with each other. Then, the imprint material R is cured by irradiating light of a predetermined wavelength after the contact, and a pattern is formed on the imprint material R in a predetermined pattern region of the substrate S. Thereafter, the mold M is released from the cured imprint material R. As a result, a film in which the pattern P is formed or a flat film in the flattening process is formed on the substrate S.

FIG. 6 is a diagram showing an example of an operation screen of the editor 600 functioning as a user interface. The editor 600 is for generating and editing the application information RP, is generated by the control unit 220, and is provided as a user interface. In the present embodiment, the editor 600 generated by the control unit 220 is managed by the console unit 210 and displayed on the monitor 201.

However, the editor 600 may be generated by the control unit 220 included in the molding apparatus IMP, or may be generated by an information processing apparatus external to the molding apparatus IMP. Similarly, the editor 600 may be displayed on the monitor 201 of the molding apparatus IMP, or may be displayed on a monitor outside the molding apparatus IMP. Here, an example in which the editor 600 is displayed on the monitor 201 will be described.

In the editor 600, the application information RP indicating the position and the amount of the imprint material R to be supplied onto the substrate S is displayed in the area 601. In addition, in the area 601, for example, there is an area 602 in which a parameter for switching between displaying the entire substrate and displaying a shot region can be set. Further, an area 603 in which parameters such as a configuration information file (Configuration file) for acquiring inspection information after imprinting can be set is provided. In addition, information acquired from the configuration information file is displayed in an area 604.

The program for operating the editor 600 may be included in the information processing apparatus 200 described in the present embodiment. Further, it may be provided on a computer (not shown) connected to the outside of the information processing apparatus 200 or the molding apparatus IMP by a wired or wireless communication line.

### EXAMPLE 1

A molding apparatus according to the present disclosure and a method of adjusting arrangement and supply of droplets of an imprint material R to a substrate surface in a nanolithography technique for mass production of a semiconductor device or a magnetic storage medium will be described with reference to the accompanying drawings.

An example of determining the arrangement of the droplets of the imprint material R on the outer peripheral portion of the substrate will be described.

When a film is formed on the substrate S, if the mold M is smaller than the substrate S, one shot region (Full Field) is repeatedly stamped to form a pattern on the film on the entire surface of the substrate S. When all of the one shot region is contained in the substrate S, the film is formed using the application information (dropping information of droplet) of the imprint material R as shown in FIG. 4. However, the shot region may include a partial region (partial field) protruding from the substrate S, and in such case, it is necessary to generate application information according to the shape of the outer periphery of the substrate S. In this specification, a portion of the substrate S where the application information needs to be changed in accordance with the shape of the substrate S is referred to as a substrate outer peripheral portion.

As a simple example of changing the application information, by comparing the coordinate information of the shape of the outer peripheral portion of the substrate with the arrangement coordinates of the imprint material R, it is possible to generate the application information by adopting only the imprint material R inside the substrate S as a droplet to be coated.

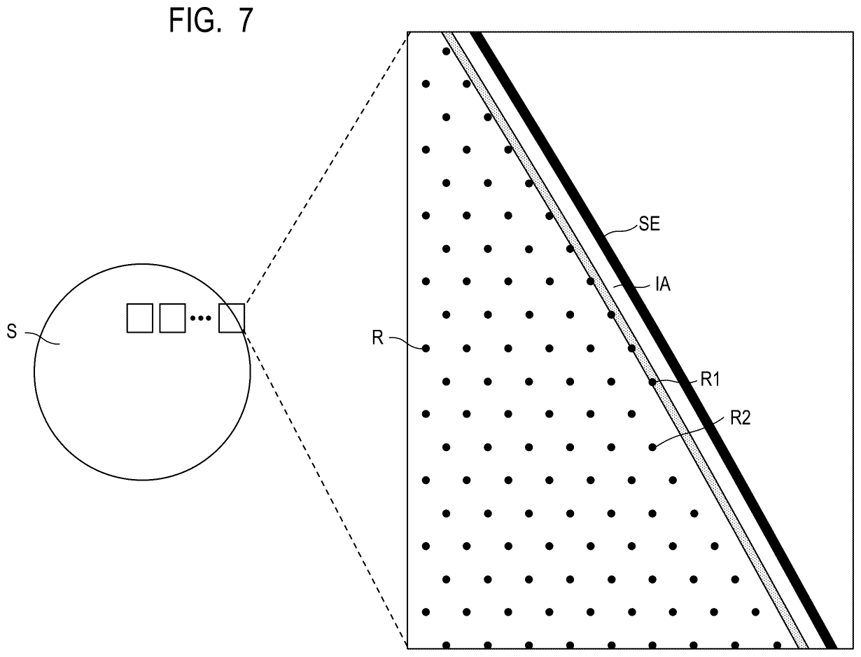

The editing of the application information by cutting out a predetermined droplet position from the droplet group in the application information of the imprint material R in one shot region (Full Field) as described above is also referred to as cutting. FIG. 7 shows an example of the cutting. FIG. 7 illustrates a substrate edge (SE) indicating the shape of the substrate outer peripheral portion and an arrangement prohibited region (IA: Invalid Area) of the droplet of the imprint material R, and the arrangement of the droplet of the imprint material R in the arrangement prohibited region IA is deleted. The arrangement prohibited region IA needs to be set in accordance with the outer peripheral shape of the substrate S.

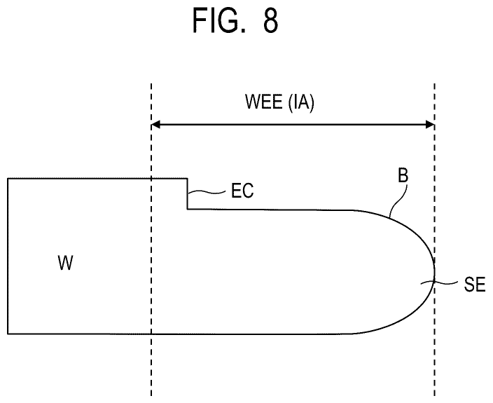

When the substrate S is a wafer W, a cross-sectional view including a perpendicular line to the substrate surface in the outer peripheral portion is as shown in FIG. 8. The wafer W has a bevel B and a step EC (Edge Cut) formed when the outer peripheral portion is chamfered in the wafer formation process. When the substrate S is a wafer W, as shown in FIG. 8, the arrangement prohibited region IA of the imprint material R is set as a wafer edge exclusion region (WEE) including the bevel B and the step EC so as not to be affected by the bevel B and the step EC.

However, depending on the arrangement of the imprint material R before the cutting, since the substrate edge SE has a curved shape in contrast to the arrangement of the imprint material R in a lattice shape, the distance between the substrate edge SE and the imprint material R varies. For example, as shown in FIG. 7, the distance between the imprint material R1 and the substrate edge SE is short, while the distance between the imprint material R2 and the substrate edge SE is long.

When the imprint material R is too close to the substrate edge SE, the imprint material R may protrude from the substrate edge SE, or when the pattern P is present in the mold M, the imprint material R may enter the pattern P, and both of them may cause a defect. On the other hand, if the distance between the imprint material R and the substrate edge SE is too long, the film thickness becomes thin, and the mold M and the substrate S come into contact with each other, which may cause deterioration in the overlay accuracy and damage to the mold M.

Such a problem is caused by not only the distance between the substrate edge SE and the imprint material R but also the density of the arrangement of the droplets of the imprint material R. When the arrangement of the droplets of the imprint material R is sparse, the film thickness becomes thin, and when the arrangement of the droplets of the imprint material R is dense, the size spreading toward the substrate edge SE becomes large. In addition, the local density variation may generate a non-uniform film or may cause the extrusion defects. In order not to generate such defects, it is necessary to adjust at least one of the position, the amount, and the presence or absence of the arrangement of the droplets of the imprint material R.

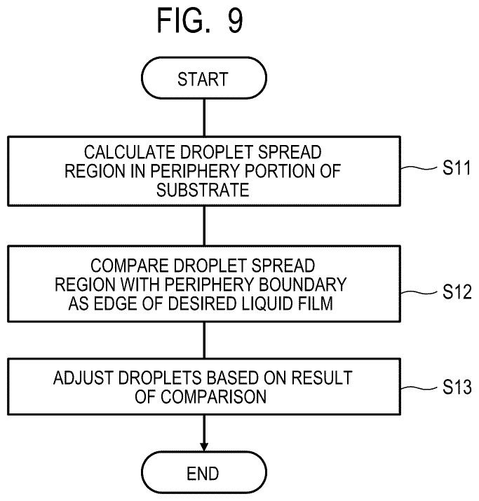

FIG. 9 shows a flowchart of a process of adjusting the arrangement of droplets of the imprint material R in the outer peripheral portion of the substrate in the present embodiment. The processing is performed by the information processing apparatus 200 illustrated in FIG. 2. The information processing apparatus 200 may be an apparatus outside the molding apparatus IMP or an apparatus configured inside the molding apparatus IMP.

In step S11, the spread region of the droplets in the outer peripheral portion of the substrate when the mold M and the droplets of the imprint material R on the substrate S are brought into contact with each other is calculated. A specific method of calculating the droplet spread region will be described later.

In step S12, the calculated droplet spread region is compared with an outer peripheral boundary OB (Outline Boundary) which is an edge of a desired liquid film set based on the outer peripheral portion of the substrate. In step S13, the arrangement of the droplets is adjusted based on the comparison result. Adjusting the arrangement of the droplets includes at least one of moving the position of the droplets, adjusting the amount of the droplets, cutting the position of the droplets (deleting the arrangement), and adding the position of the droplets (adding the arrangement).

After the end of step S13, the process from step S11 is performed based on the arrangement of the droplets adjusted in step S13, and the process of FIG. 9 is continued until a predetermined convergence condition is satisfied. More specifically, a Voronoi diagram based on the arrangement of the droplets adjusted in step S13 is acquired by geometric calculation, and the processing from step S11 is performed.

Here, as the predetermined convergence condition, for example, a convergence condition may be set such that the difference between the values obtained in the N-th and (N−1)-th processing flows of FIG. 9 is within a predetermined range with respect to at least any of the position and the amount of each of the plurality of droplets and the number of the plurality of droplets.

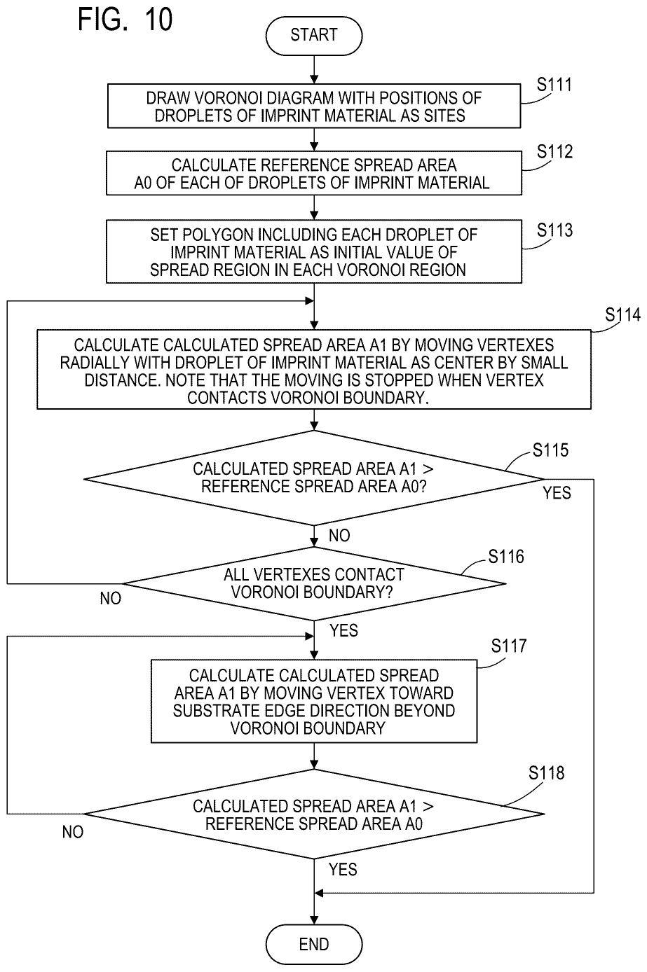

An example of a specific method of calculating the droplet spread region in the outer peripheral portion of the substrate in step S11 will be described with reference to FIG. 10. FIG. 10 is a flowchart for deriving a spread region for each droplet of the imprint material R based on the Voronoi diagram VD. The Voronoi diagram is a diagram in which, in a case where a plurality of points (sites) (the positions of the droplets of the imprint material R in the present disclosure) are arranged on a plane, regions are divided according to which site a point at an arbitrary position in the plane is closest to.

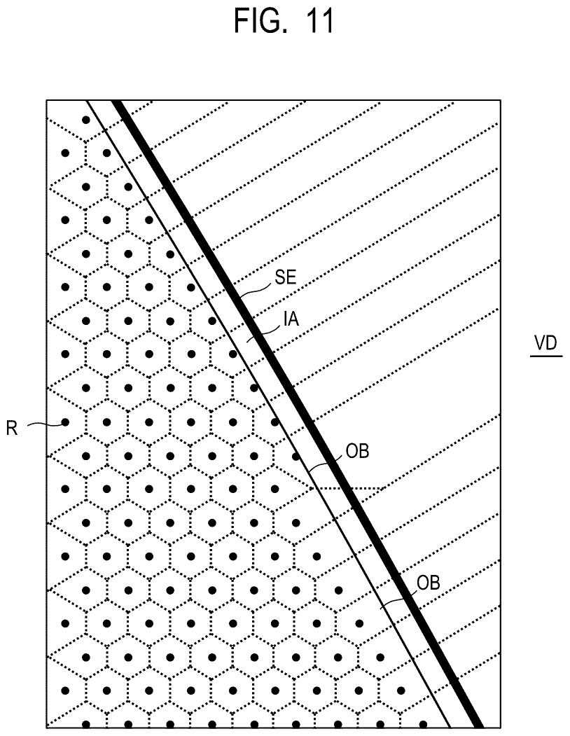

In step S111, first, the Voronoi diagram VD is created using the positions of the droplets of the imprint material R as sites. FIG. 11 shows an example of a Voronoi diagram VD created using the positions of the droplets of the imprint material R in FIG. 7 as sites. In FIG. 7, the substrate edge SE is indicated by a thick solid line, the outer peripheral boundary OB of the arrangement prohibited region IA of the droplet spread region of the imprint material R is indicated by a thin solid line, and the Voronoi boundary is indicated by a broken line.

In step S112, a reference spread area (area threshold value) A0 for each imprint material R is calculated. The reference spread area A0 can be calculated, for example, by dividing the volume of each imprint material R by the thickness of the liquid film after desired film formation. Further, when there is information relating to unevenness of the base and/or the pattern P of the mold M, calculation may be performed in consideration of the volume of the pattern P based on the volume of the imprint material R.

In step S113, in each Voronoi region, a polygon containing each droplet of the imprint material R is set as an initial value of a spread region for the droplet.

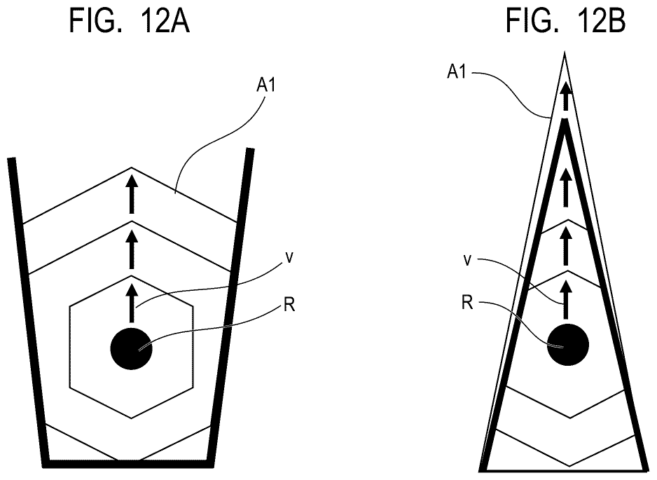

In step S114, the vertex of the polygon is radially expanded by a unit movement distance v with the imprint material R being as center, and the area (calculated expansion area) A1 of the polygon at that time is calculated. The process of radially expanding the vertex of the polygon by the unit movement distance v with the imprint material R being as the center will be described later with reference to FIGS. 12A and 12B. By setting a small value for the unit movement distance v, it is possible to minutely change the calculated spread area A1 for the unit movement distance v.

The number of corners (spread vertices) of the polygon can be arbitrarily set. As the number of vertices increases, the shape of the region having the contour of the vertices can be made closer to a circle, and a state close to an actual spreading manner in which the region spreads around the position of the droplet can be obtained, but the calculation amount increases, and therefore, the number of vertices may be appropriately set according to the application condition. The vertex is expanded until it contacts the Voronoi boundary of the Voronoi diagram VD created in advance, and the vertex which contacted the Voronoi boundary stops moving.

In step S115, the calculated spread area A1 is compared with the reference spread area A0, and when the calculated spread area A1 is larger than the reference spread area A0, the movement of all the vertices is stopped, and the process is ended. In this case, the spread region is a region obtained by the expanding from the initial state until the area of the spread region of the droplet becomes larger than a predetermined area threshold value (for example, based on the volume of the droplet and the designed thickness after the film formation). Thus, the spread shape of the droplets of the imprint material R can be acquired.

In step S115, when the calculated spread area A1 is smaller than the reference spread area A0, the process proceeds to step S116. In this case, when the mold M is pressed against the imprint material R on the substrate S, there is a possibility that the imprint material R may spread beyond the spread region of the imprint material R into the spread region of the adjacent imprint material R, and thus it is necessary to further widen the spread region of the imprint material R.

In step S116, it is checked whether all the vertices are in contact with the Voronoi boundary. If all the vertices are in contact with the Voronoi boundary, the process proceeds to step S117, and if there is a vertex that is not in contact with the Voronoi boundary, the process returns to step S114.

When the process returns from step S116 to step S114, as shown in FIG. 12A, all the vertices are in one Voronoi region surrounded by the Voronoi boundary in the outward spread of the vertices. In this case, the calculated spread area A1 is equal to or smaller than the reference spread area A0, and at least one vertex is not yet in contact with the Voronoi boundary in the process of spreading outward of the vertex. The Voronoi region centered on the droplet of the imprint material R in this state is defined as an open Voronoi region in this specification.

When the process proceeds from step S116 to step S117, as shown in FIG. 12B, the calculated spread area A1 is equal to or smaller than the reference spread area A0, and at least one vertex is outside the Voronoi region of the imprint material R. The Voronoi region centered on the droplet of the imprint material R in this state is defined herein as a closed Voronoi region.

In step S117, the calculated spread area A1 is calculated by moving the vertex toward the outer peripheral side of the substrate S by a minute distance beyond the Voronoi boundary in the substrate edge direction. The direction in which the vertex expands depends on the arrangement of the surrounding imprint material R, but the closer to the outer peripheral portion of the substrate, the weaker the force of pushing back the imprint material R of interest, so that the other imprint material R expands in the edge direction. In particular, it spreads in the direction of the outer peripheral portion of the substrate, which is the Voronoi point farthest from the imprint material R of interest. The spread region obtained in step S117 is a region configured by a polygon in which all the vertices are on the Voronoi boundary of the Voronoi region of the droplet or outside the Voronoi region.

Thereafter, the process proceeds to step S118, and the calculated spread area A1 acquired in step S117 is compared with the reference spread area A0. If the calculated spread area A1 is equal to or smaller than the reference spread area A0, the process returns to step S117, and if the calculated spread area A1 is greater than the reference spread area A0, the process ends. In this way, steps S117 and S118 are repeated until the calculated spread area A1 becomes larger than the reference spread area A0.

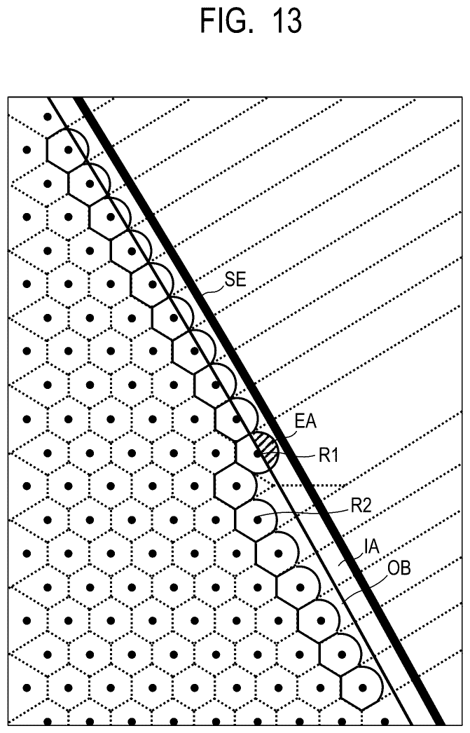

By calculating the spread shape for each droplet of the imprint material R calculated in this manner, the spread shape after film formation with respect to the substrate edge can be calculated. FIG. 13 is an example of a spread shape calculated using the spread shape calculation flow shown in FIG. 10. The portion of the spread shape shown in FIG. 13 closest to the substrate edge has an arc shape centered on each droplet of the imprint material R because the spread shape is constituted by a polygon formed by many vertices which are arbitrarily set.

It can be seen that, in the imprint material R1, the area (EA: Extrusion Area, the region indicated by oblique lines) in which the droplet spread region extrudes into the arrangement prohibited region IA of the imprint material R is large. Conversely, it can be seen that the droplet spread region of the imprint material R2 is far from the substrate edge SE.

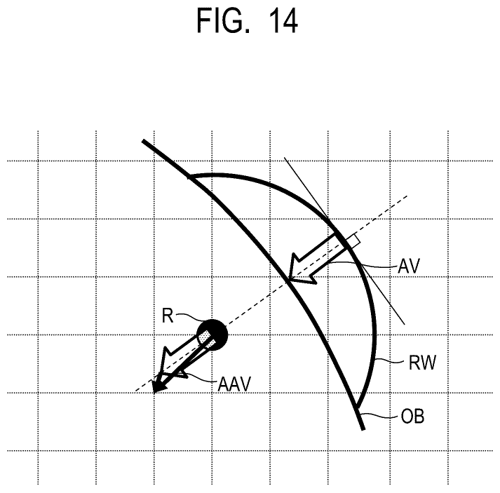

Next, in step S12 of FIG. 9, the calculated droplet spread region is compared with the outer peripheral boundary OB which is the edge of the desired liquid film. In the comparative example illustrated in FIGS. 14 to 16, a spread shape (RW: Resist Wavefront) in the substrate edge direction calculated based on the imprint material R and an outer peripheral boundary OB serving as a target of a boundary on the edge side of the spread shape RW are illustrated. The outer peripheral boundary OB and the above-described arrangement prohibited region IA of the imprint material R are both set to a shape along the shape of the substrate outer peripheral portion, and therefore, the same value may be used, or different values may be used in the sense of a target shape after film formation.

Here, the outer peripheral boundary OB will be described in detail. Basically, in accordance with the shape of the outer peripheral portion of the substrate, the outer peripheral boundary OB can be set at a position at a constant distance inward from the outer peripheral portion of the substrate. However, the outer peripheral boundary OB may be partially set to the inside or the outside of the substrate S by using a value using an arbitrary input parameter in accordance with the pattern P of the mold M or the concave-convex shape of the substrate surface of the substrate S.

For example, in a case where a part of the outer peripheral portion of the substrate is recessed in a direction perpendicular to the substrate surface, since the resist is accommodated in the recessed portion and is less likely to spread outward in the radial direction of the substrate S, the outer peripheral boundary OB may be set on the outer peripheral side than in a case where the recessed portion is not provided. As a result, it is possible to more accurately predict the spread of the imprint material R to a region from the substrate outer peripheral portion to a certain distance while preventing the imprint material R from spreading out to the substrate outer peripheral portion.

Further, the outer peripheral boundary OB may be set based on an actual measured value obtained by actually measuring the shape of the substrate S. For example, actual measurement values such as the contour shape of the outer periphery of the substrate S, the concave-convex shape of the surface of the substrate S, and the distribution of the thickness of the substrate S may be used to reflect the actual measurement values in the setting of the outer periphery boundary OB. By setting the outer peripheral boundary OB based on the actual measurement value, it is possible to more accurately predict the spread of the imprint material R to a region from the outer peripheral portion of the substrate to a certain distance while suppressing the influence of variation in the shape of the substrate S due to a manufacturing error or the like and preventing the imprint material R from extruding out to the outer peripheral portion of the substrate.

FIG. 14 shows a case where the spread shape RW is outside the target outer peripheral boundary OB. The purpose of the arrangement adjustment of the droplets of the imprint material R is to arrange the droplets of the imprint material R so that the spread shape RW approaches the outer peripheral boundary OB. For example, in the vicinity of the outer peripheral boundary OB, a vector to the outer peripheral boundary OB in the normal direction (perpendicular direction to the tangent line) of the spread shape RW can be calculated based on the fact that the spread shape RW spreads in an arc shape centered on the position of the droplet of the imprint material R, and can be used for arrangement adjustment of the imprint material R.

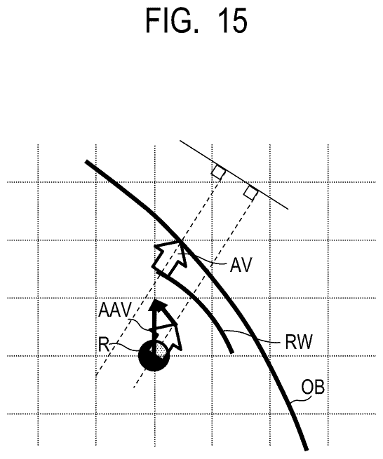

FIG. 15 shows a case where the spread shape RW is located in the center side (inner side) of the substrate with respect to the target outer peripheral boundary OB. In this case, a vector having the longest distance from the outer peripheral boundary OB in the normal direction of the spread shape RW is calculated. In both FIGS. 14 and 15, by comparing the spread shape RW and the outer peripheral boundary OB, it is possible to calculate the points at which the two lines are farthest from each other in the normal direction of the spread shape RW and to use the points for the arrangement adjustment of the imprint material R.

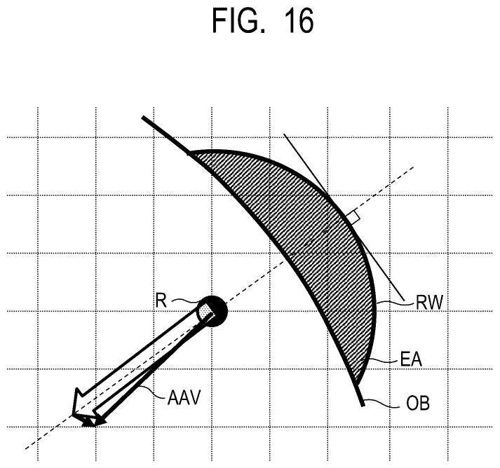

Similarly to FIG. 14, FIG. 16 shows a case where the spread shape RW is outside the target outer peripheral boundary OB. Based on the size of the area (extended area) EA of the region surrounded by the spread shape RW and the outer peripheral boundary OB, it can be used to adjust the arrangement of the imprint material R.

As described above, the vector and the extended area EA can be calculated from the comparison information as the feature amount for adjusting the application information of the imprint material R.

In the molding apparatus IMP using the dispenser D, there is a restriction in the positions of the droplets that can be disposed due to the structure of the dispenser D, which is a head for applying the droplets of the imprint material R onto the substrate S. In general, since a plurality of nozzles disposed in the dispenser D is disposed at equal interval NP (Nozzle Pitch) and the positions of the nozzles are fixed, it is not possible to discharge droplets at positions between the nozzles.

In addition, by controlling a reciprocation of the dispenser D, it is possible to discharge the droplets in the return path at a position where the droplets could not be discharged in the forward path. However, increasing the number of reciprocations causes a deterioration of through put and an elongation of time to the film formation process which may cause an evaporation of the resist liquid droplets discharged in advance, which is a problem. Therefore, when adjusting the liquid droplets, it is necessary to adjust the arrangement of the liquid droplets in accordance with the restriction. The following adjustment example of the imprint material R is an example in which the minimum unit of the movement of the liquid droplets can be moved only at a predetermined pitch in the vertical and horizontal directions depending on the interval NP between the nozzles.

In step S13 of FIG. 9, the arrangement or the like of the droplets is adjusted based on the comparison result between the calculated droplet spread shape RW obtained in step S12 and the outer peripheral boundary OB which is the edge of the desired liquid film. An example in which the arrangement of the imprint material R is adjusted by the calculated vector will be described with reference to FIGS. 14 and 15. A method of acquiring an actual adjustment vector (AAV) on the basis of an adjustment vector (AV) calculated on the basis of a comparison between the spread shape RW and the outer peripheral boundary OB and on the basis of a constraint in discharge of the dispenser D will be described below.

One example of a method of calculating the adjustment vector AAV is shown.

First, the normal direction of the tangent to the spread shape RW (Resist Wavefront) is calculated. In the normal direction at each position of the edge of the spread shape RW, a vector connecting two points at which the distance between the edge of the spread shape RW and the outer peripheral boundary (OB: Outline Boundary) is the longest can be set as the calculated adjustment vector AV (see FIGS. 14 and 15). First, coordinates obtained by applying the adjustment vector AV to the coordinates of the imprint material R are calculated.

As described above, due to the functional constraints of the dispenser D, there are constraints on the positions where the droplets of the imprint material R can be disposed, and for example, in FIGS. 14 and 15, the droplets can be disposed only at the intersections indicated by the broken-line grids. Therefore, the dischargeable position closest to the calculated coordinates is set as the actual adjustment vector AAV. By adjusting the discharging coordinates of the droplets of the imprint material R so as to move toward the inside of the substrate S by the adjustment vector AAV (movement amount, movement direction), it is possible to improve the area extruding outward from the outer peripheral boundary OB so as to be small.

FIG. 16 is an example of determining an adjustment direction (actual adjustment vector AAV) for adjusting the direction from the normal direction of the tangent line of the spread shape RW toward the inside of the substrate S. The adjustment direction may be a direction from the center of gravity of a region formed from the spread shape RW and the outer peripheral boundary OB to the imprint material R. As for the magnitude of the vector, a unit area of the extruded area EA corresponding to the magnitude of the distance may be determined in advance, and the magnitude of the movement may be obtained from the calculated extruded area EA. When the size of the calculated extruded area EA exceeds a predetermined threshold, the position of the droplet of the imprint material R may be removed.

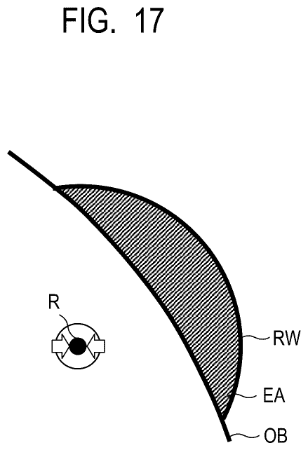

FIG. 17 shows an example in which the discharging volume amount of the imprint material R is changed. When the discharging amount of the imprint material R discharged from the dispenser can be changed, the discharge amount of the imprint material R can also be adjusted by calculating the volume from the multiplication of the calculated extruded area EA and the film thickness. In this case, since it is not necessary to change the discharging position of the imprint material R, the influence of the spread shape of the surrounding imprint material R is reduced.

By changing the discharging position of the imprint material R, it is easy to obtain an effect of correction and it is suitable for rough adjustment. Although the adjustment of the discharging amount of the imprint material R is suitable for fine adjustment, since there is a limitation in the range in which the discharging amount can be changed, the rough adjustment may be performed by the adjustment at the discharging position, and the fine adjustment may be performed by the adjustment at the discharging amount.

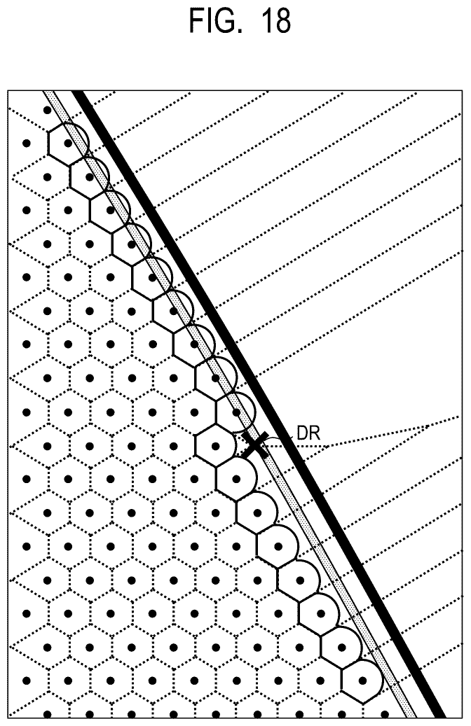

An example after adjustment is shown. FIG. 18 is an example in which the position of the imprint material R1 is deleted from the extruded area EA of FIG. 13. An arbitrary threshold value for the extruded area EA may be compared with the extruded area EA, and if the extruded area EA is equal to or larger than the threshold value, the extruded area EA may be deleted. By deleting (DR: Delete Resist) the imprint material R1 at the x-marked coordinates, the total extruded amount becomes small.

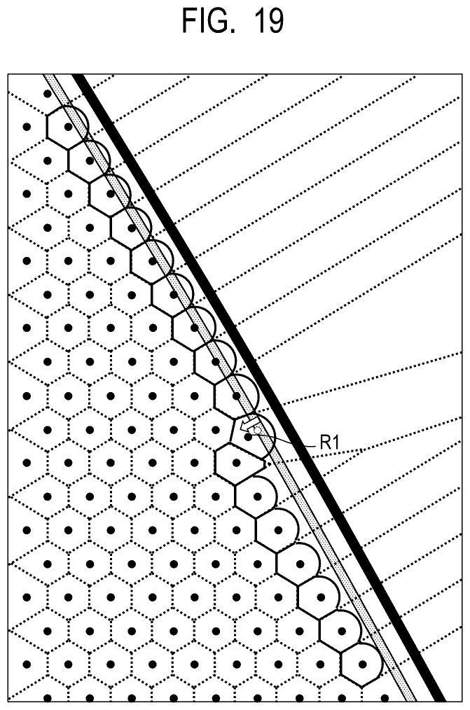

FIG. 19 is an example in which the arrangement of the imprint material R is adjusted from FIG. 13. The extruded area EA is improved by moving the imprint material R1 inward. By repeating the adjustment in each imprint material R, the total extruded amount is improved.

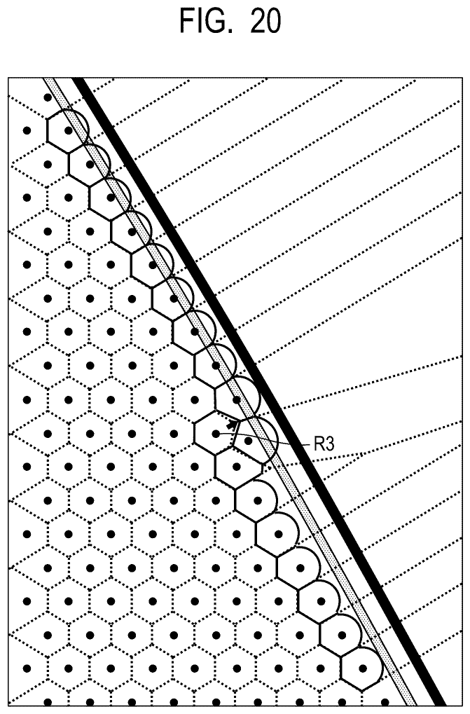

FIG. 20 is an example showing a spread in a case where the droplets of the imprint material R3 whose Voronoi region obtained by recalculation becomes smaller spread outward beyond the Voronoi boundary when the imprint material R1 in the vicinity of the edge is moved inward as shown in FIG. 19. This corresponds to the case of the spreading of the closed Voronoi region described with reference to FIG. 12B. When an angle formed by the substrate edge direction at each of the plurality of Voronoi points and a direction from the position of the imprint material R to each of the plurality of Voronoi points is different from each other, the spread can be calculated in consideration of the angle with respect to each of the Voronoi points.

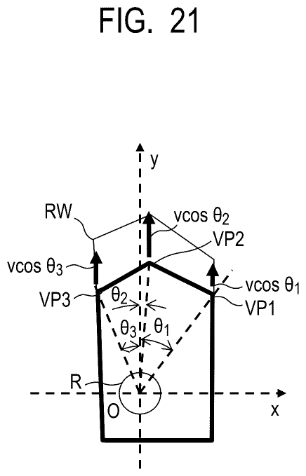

A method of calculating the spread beyond the Voronoi region will be described with reference to FIG. 21. With the imprint material R as the origin O, the substrate edge is located on the y-axis positive direction side with respect to the origin O, and the Voronoi points VP1, VP2, and VP3 of the Voronoi region are located on the y-axis positive direction side with respect to the origin O. Regarding the relationship between the imprint material R and the substrate edge direction at each Voronoi point, for example, angles between a straight line connecting the imprint material R and each of the Voronoi points VP1, VP2, and VP3 and the positive direction of the x axis are θ1, θ2, and θ3, respectively.

In the example shown in FIG. 21, |dθ2|<|dθ3|<|dθ1| is satisfied. Therefore, the droplet at the Voronoi point VP2 is more likely to spread toward the edge direction than the droplet at the Voronoi points VP1 and VP3. In FIG. 21, the spread easiness toward the edge direction of the droplet at each of the Voronoi points VP1, VP2, and VP3 is represented by multiplying the unit movement distance v by a coefficient, cos θ. Here, θ is an angle of the edge direction with respect to a straight line connecting the imprint material R and the Voronoi point.

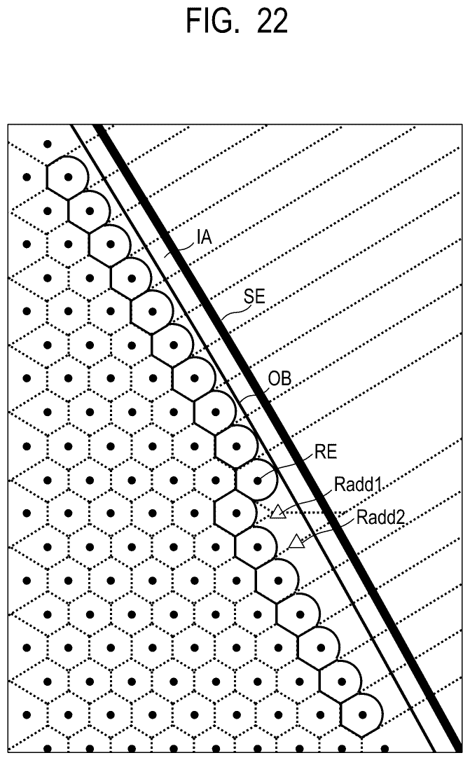

FIG. 22 shows a case where droplets are added, in contrast with the deletion of droplets shown in FIG. 18, based on the comparison between the outer peripheral boundary OB and the spread region of droplets in step S12 of the processing flow of FIG. 10. Additional candidates for droplets (Radd1, Radd2) were illustrated in FIG. 22. The position and the droplet amount of the additional candidate droplet may be set based on the distance between the outer peripheral boundary OB and the edge of the spread region of the droplet, the position of the adjacent droplet, the amount of the droplet, and the like.

As described above, it is possible to predict the spread of the substrate outer peripheral portion and adjust the arrangement (position, amount, and presence or absence of the arrangement) of the imprint material R from the prediction result. The exemplified technique can be used in a nanoimprint lithography apparatus for transferring a pattern onto a substrate S or a flattening apparatus for planarizing unevenness of a substrate surface with an imprint material R.

### Article Manufacturing Method Embodiment

The pattern of the cured product formed through the forming step of performing imprint processing using the molding apparatus of the present disclosure is used permanently for at least a part of various articles or temporarily when various articles are manufactured. The article is an electric circuit element, an optical element, MEMS (Micro Electro Mechanical System), a recording element, a sensor, a mold, or the like. Examples of the electric circuit element include volatile or nonvolatile semiconductor memories such as DRAM(Dynamic Random Access Memory), SRAM(Static Random Access Memory), flash memory, and MRAM (Magnetoresistive Random Access Memory), and semiconductor elements such as large scale integration (LSI), charge coupled device (CCD), image sensor, and FPGA (Field Programmable Gate Array). Examples of the mold include a mold for imprinting.

The pattern of the cured product is used as it is or temporarily used as a resist mask as a component of at least a part of the article. After etching, ion implantation, or the like is performed in the processing step of the substrate, the resist mask is removed.

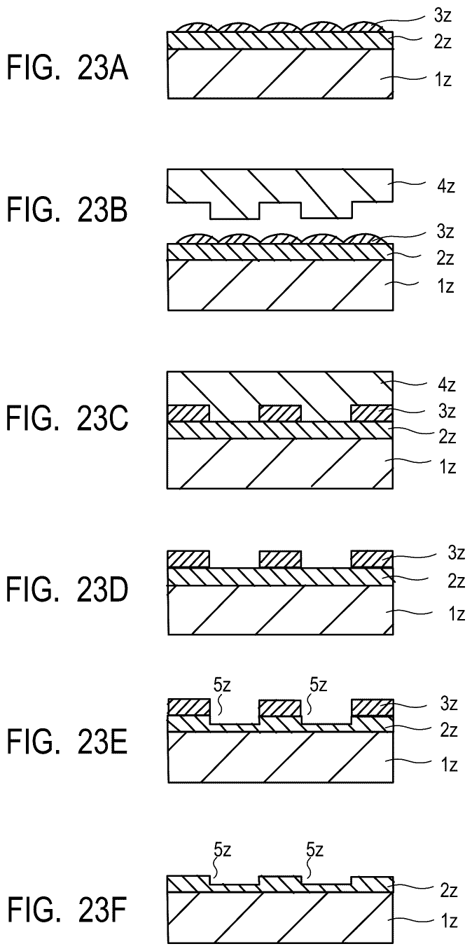

Next, a specific method of manufacturing an article will be described. As shown in FIG. 23A, a substrate 1z such as a silicon wafer on which a workpiece 2z such as an insulator is formed is prepared, and subsequently, a composition 3z is applied onto the surface of the workpiece 2z by an inkjet method or the like. Here, a state in which the composition 3z in the form of a plurality of droplets is applied onto the substrate 1z is shown.

As shown in FIG. 23B, the mold 4z for imprinting is opposed to the composition 3z on the substrate with the side on which the concave-convex pattern is formed facing the composition 3z. As illustrated in FIG. 23C, the substrate 1z to which the composition 3z has been applied is brought into contact with the mold 4z, and pressure is applied. The gap between the mold 4z and the workpiece 2z is filled with the composition 3z. In this state, when light is irradiated through the mold 4z as curing energy, the composition 3z is cured.

As shown in FIG. 23D, when the mold 4z and the substrate 1z are separated from each other after the composition 3z is cured, a pattern of a cured product of the composition 3z is formed on the substrate 1z. In the pattern of the cured product, the concave portion of the mold 4z has a shape corresponding to the convex portion of the cured product and the convex portion of the mold 4z has a shape corresponding to the concave portion of the cured product, that is, the concave-convex pattern of the mold 4z is transferred to the composition 3z.

As shown in FIG. 23E, when etching is performed using the pattern of the cured product as an etching-resistant mask, a portion of the surface of the workpiece 2z where the cured product does not exist or remains thinly is removed to form a groove 5z. As illustrated in FIG. 23F, when the pattern of the cured product is removed, an article in which the grooves 5z are formed on the surface of the workpiece 2z can be obtained. Although the pattern of the cured product is removed here, it may be used as a film for interlayer insulation included in a semiconductor element or the like, that is, as a constituent member of an article, for example, without being removed even after processing. Although an example in which a mold for transferring a circuit pattern provided with a concave-convex pattern is used as the mold 4z has been described, a mold (planar template) having a planar portion without a concave-convex pattern may be used.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-201655, filed Nov. 19, 2024, which is hereby incorporated by reference herein in its entirety.

What is claimed is:

1. A molding apparatus for forming a liquid film comprising a curable composition in a space between a substrate and a mold by bringing the mold into contact with a plurality of droplets of the curable composition disposed on the substrate, comprising,
a control unit configured to determine an adjustment method of an arrangement of the plurality of droplets based on a spread region which is acquired based on the arrangement of the plurality of droplets on the substrate and is a region where the plurality of droplets spread due to the contact with the mold, and an outer peripheral boundary determined based on a shape of an outer peripheral portion of the substrate.

2. The molding apparatus according to claim 1, wherein the control unit acquires the spread region by a geometric calculation based on the arrangement of the plurality of droplets on the substrate.

3. The molding apparatus according to claim 1, wherein the control unit acquires the spread region based on a Voronoi diagram created using each of the plurality of droplets on the substrate as a site.

4. The molding apparatus according to claim 3, wherein the control unit acquires the spread region as a region obtained by expanding the area of the spread region of the plurality of droplet from an initial state set as a region including the plurality of droplets in a Voronoi region of the Voronoi diagram for each of the plurality of droplets until the area of the spread region of the plurality of droplets becomes larger than a predetermined area threshold.

5. The molding apparatus according to claim 4, wherein the control unit acquires the spread region as a region obtained by spreading each vertex of a polygon, located in the Voronoi region, around the site.

6. The molding apparatus according to claim 4, wherein the control unit acquires the spread region as a region configured by a polygon in which all vertices are located on a Voronoi boundary of the Voronoi region of the droplet or outside the Voronoi region.

7. The molding apparatus according to claim 6, wherein the control unit acquires the spread region as a region obtained by moving at least one vertex of the polygon toward an outer periphery of the substrate.

8. The molding apparatus according to claim 1, wherein the control unit sets the outer peripheral boundary based on a concave-convex shape of a substrate surface of the substrate.

9. The molding apparatus according to claim 1, wherein the control unit sets the outer peripheral boundary based on a contour shape of the outer periphery of the substrate.

10. The molding apparatus according to claim 8, wherein the control unit sets the outer peripheral boundary based on an actual measurement value of a shape of the substrate.

11. The molding apparatus according to claim 1, wherein the adjustment method includes determining a movement direction and a movement amount of the position of the droplet based on the outer peripheral boundary and an edge of the spread region.

12. The molding apparatus according to claim 1, wherein the adjustment method includes at least one of deletion or addition of the arrangement of the droplets.

13. The molding apparatus according to claim 1, wherein the adjustment method includes adjusting the position of the droplet based on a vector connecting two points having a longest distance between the outer peripheral boundary and the edge in a normal direction at each position of the edge of the spread region.

14. The molding apparatus according to claim 1, wherein the adjustment method includes performing an adjustment on the droplets in the spread region in which an area in an outer peripheral side of the outer peripheral boundary is larger than a threshold value.

15. The molding apparatus according to claim 1, comprising an imprint apparatus that forms a pattern of a cured product on the substrate,
wherein the mold has a surface having a concave-convex pattern.

16. The molding apparatus according to claim 1, comprising a flattening apparatus that flattens the surface of the substrate,
wherein the mold is a mold having a flat surface.

17. An information processing apparatus for determining an adjustment method of arrangement of a plurality of droplets in a molding apparatus that forms a liquid film made of the curable composition in a space between a substrate and a mold by bringing the mold into contact with the plurality of droplets of the curable composition disposed on the substrate, comprising
a control unit configured to determine the adjustment method of the arrangement of the plurality of droplets based on a spread region that is acquired based on the arrangement of the plurality of droplets on the substrate and is a region where the plurality of droplets spread due to a contact with the mold and an outer peripheral boundary determined based on a shape of an outer peripheral portion of the substrate.

18. A molding method in which a mold is brought into contact with a plurality of droplets of a curable composition disposed on a substrate to form a liquid film made of the curable composition in a space between the substrate and the mold, comprising:
acquiring a spread region, which is a region where the plurality of droplets spreads due to a contact with the mold, based on an arrangement of the plurality of droplets on the substrate;
determining an outer peripheral boundary based on a shape of an outer peripheral portion of the substrate; and
adjusting the arrangement of the plurality of droplets based on the spread region and the outer peripheral boundary.

19. A non-transitory computer-readable storage medium storing a program for causing a computer to execute a molding method in which a mold is brought into contact with a plurality of droplets of a curable composition disposed on a substrate to form a liquid film made of the curable composition in a space between the substrate and the mold,
wherein the molding method includes:
acquiring a spread region, which is a region where the plurality of droplets spreads due to a contact with the mold, based on an arrangement of the plurality of droplets on the substrate;
determining an outer peripheral boundary based on a shape of an outer peripheral portion of the substrate; and
adjusting the arrangement of the plurality of droplets based on the spread region and the outer peripheral boundary.

20. A method of manufacturing an article, comprising:
a molding step of forming a pattern on a substrate using a plurality of droplets of a curable composition disposed on the substrate based on an adjustment method determined by a molding apparatus;
a processing step of processing the substrate on which the pattern is formed in the molding step; and
a manufacturing step of the article from the substrate processed in the processing step,
wherein the molding apparatus forms a liquid film comprising a curable composition in a space between a substrate and a mold by bringing the mold into contact with a plurality of droplets of the curable composition disposed on the substrate, includes, a control unit configured to determine an adjustment method of an arrangement of the plurality of droplets based on a spread region which is acquired based on the arrangement of the plurality of droplets on the substrate and is a region where the plurality of droplets spread due to the contact with the mold, and an outer peripheral boundary determined based on a shape of an outer peripheral portion of the substrate.
